(19) United States
(12) Patent Application Publication
(10) Pub. No.: US 2023/0396029 A1
(43) Pub. Date: Dec. 7, 2023

(54) Plug with LED indicating light

(71) Applicant: Jeremy Madvin, Westlake Village, CA (US)

(72) Inventor: Jeremy Madvin, Westlake Village, CA (US)

(21) Appl. No.: 17/829,385

(22) Filed: Jun. 1, 2022

(51) Int. Cl. H01R 13/717; H05K 9/00

(52) U.S. Cl. CPC H01R 13/7175; H05K 9/0064

(57) ABSTRACT

The present invention discloses an enhanced design of USB plug device which is universal in nature. It indicates the biological or non-biological body is properly grounded by using indicator lights. The proposed assembly is easy to use, compact, safe and maintain its effectiveness over longer period of time.

### COPYRIGHT NOTICE

A portion of the disclosure of this patent document contains material which is subject to copyright protection. The copyright owner has no objection to the facsimile reproduction by anyone of the patent disclosure, as it appears in the Patent and Trademark Office patent files or records, but otherwise reserves all copyright rights whatsoever.

### BACKGROUND

### Field of the Invention

The present invention relates to a grounding device and more particularly relates to a USB plug designed for the sole purpose of facilitating the grounding a biological or non-biological body.

### Description of the Related Art

Grounding or earthing refers to skin contact with the surface of the Earth, such as with bare feet or hands, or with various grounding systems. Subjective reports that walking barefoot on the Earth enhances health and provides feelings of well-being can be found in the literature and practices of diverse cultures from around the world. For a variety of reasons, many individuals are reluctant to walk outside barefoot, unless they are on holiday at the beach. Experience and measurements show that sustained contact with the Earth yields sustained benefits. Various grounding systems are available that enable frequent contact with the Earth, such as while sleeping, sitting at a computer, or walking outdoors. These are simple conductive systems in the form of sheets, mats, wrist or ankle bands, adhesive patches that can be used inside the home or office, and footwear. These applications are connected to the Earth via a cord inserted into a grounded wall outlet or attached to a ground rod placed in the soil outside below a window. For the footwear applications, a conductive plug is positioned in the shoe sole at the ball of the foot, under the metatarsals, at the acupuncture point known as Kidney. From a practical standpoint, these methods offer a convenient and routine, user-friendly approach to grounding or earthing.

Recently, a group of about a dozen researchers have been studying the physiological effects of grounding from a variety of perspectives. This research has led to more than a dozen studies published in peer-reviewed journals. While most of these pilot studies involved relatively few subjects, taken together, the research has opened a new and promising frontier in inflammation research, with broad implications for prevention and public health. The findings merit consideration by the inflammation research community, which has the means to verify, refute, or clarify the interpretations we have made thus far.

There are multiple inventions that can be seen in prior art in similar regards with the purpose of facilitating the users with grounding device. However, these solutions are limited and restricted to their conventional architecture, installation system and have considerable shortcomings which adversely affect the convenience with which they can be used. The prior systems have certain limitations including the design of assemblies which make them not suitable for every type of user. Moreover, the ease-of-use ability of these assemblies is also questionable.

It has to be noted that the current invention proposes an assembly with multiple advancements including a structure facilitating the grounding of a biological or non-biological body. The light illuminates when the grounding is taking place, and only when taking place. If at any point in time the biological or non-biological body connected is not grounding, the light will not turn on.

None of the previous inventions or patents, taken either singly or in combination, are seen to describe the instant invention as claimed. Hence, the inventor of the present invention proposes to resolve and surmount existent technical difficulties to eliminate the aforementioned shortcomings of prior art.

### SUMMARY

In light of the disadvantages of the prior art, the following summary is provided to facilitate an understanding of some of the innovative features unique to the present invention and is not intended to be a full description. A full appreciation of the various aspects of the invention can be gained by taking the entire specification, claims, drawings, and abstract as a whole.

The primary desirable object of the present invention is to provide a novel and improved form of simple, non-invasive and accessible USB plug designed to facilitate he grounding of a biological or non-biological body.

It is another objective of the invention to provide a device where the light illuminates when the grounding of a biological or non-biological body is taking place.

It is further the objective of the invention to provide a simple device which is universal in nature and works with the acupressure grounding probe, the grounding massager, a grounding pad or any other device meant to ground a biological or non-biological body.

It is also the objective of the invention to provide a device of the type described which has simple structure and can be used without any training.

The present inventions provide a new type of USB connector, and more particularly a USB plug, which is adapted to connect with a standard USB socket.

It is another objective of the invention to provide a device that is crafted from very firm metal, alumina or some other material which can be used over longer period of time.

It is moreover the objective of the invention to provide assembly which is a simple but efficient device to determine effective grounding.

A further object is to provide an assembly that is simple, rapidly adjusted and easy to use.

A still further object is to provide an assembly that is economical in cost to manufacture.

Other aspects, advantages and novel features of the present invention will become apparent from the detailed description of the invention when considered in conjunction with the accompanying drawings.

This Summary is provided merely for purposes of summarizing some example embodiments, so as to provide a basic understanding of some aspects of the subject matter described herein. Accordingly, it will be appreciated that the above-described features are merely examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention and explain various principles and advantages of those embodiments.

FIG. 1 illustrates assembly in accordance with an embodiment of the present disclosure.

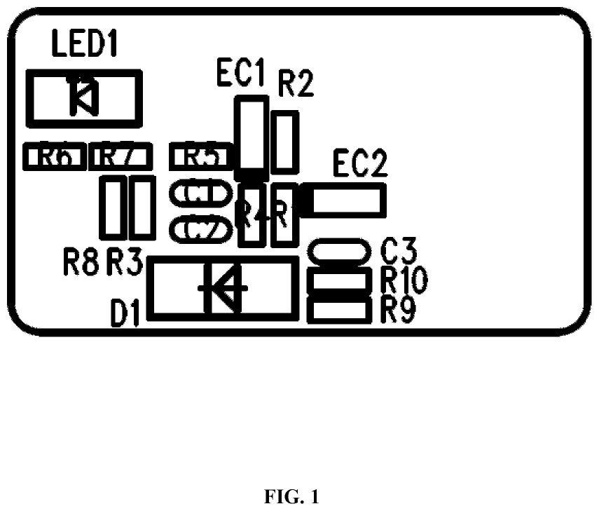

FIG. 2 illustrates another view of assembly in accordance with an embodiment of the present disclosure.

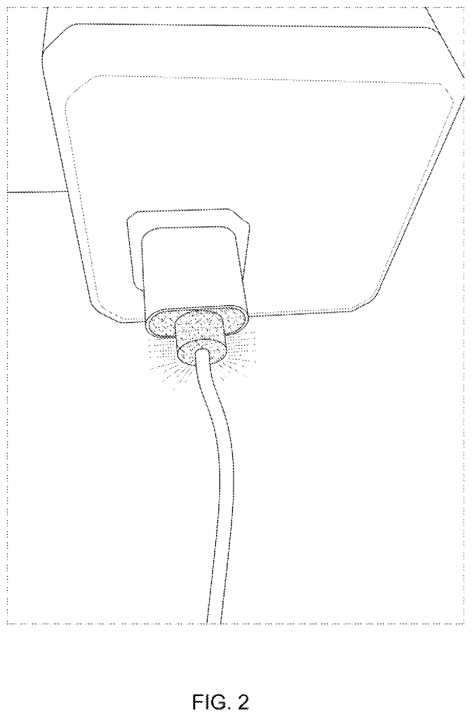

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

The terminology used herein is for the purpose of describing particular embodiments only and is not intended to be limiting of the invention. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

The present invention is directed to a USB plug designed for the sole purpose of facilitating the grounding a biological or non-biological body. The light illuminates when the grounding process starts and continues to illuminate during continuous grounding. The light ceases to illuminate during periods of interruption or when grounding is ceases to take place. The proposed USB plug is adapted for connecting with a conventional standard USB socket in both upside- and upside-down orientation.

The assembly works in a way where the computer terminal is grounded, the proposed USB plug with grounding indicator light is connected to the terminal and when a biological or non-biological body (the finger) touches the grounding device connected to the USB, the light illuminates.

While a specific embodiment has been shown and described, many variations are possible. With time, additional features may be employed. The particular shape or configuration of the platform or the interior configuration may be changed to suit the system or equipment with which it is used.

Having described the invention in detail, those skilled in the art will appreciate that modifications may be made to the invention without departing from its spirit. Therefore, it is not intended that the scope of the invention be limited to the specific embodiment illustrated and described. Rather, it is intended that the scope of this invention be determined by the appended claims and their equivalents.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

I: A device for checking the integrity of grounding devices used to determine whether a biological or non-biological body is grounded, comprising:
a USB plug;
b. an electrically conductive cord that leads to a device designed to make contact with the body which is to be grounded.
a lightning indicator; and,
a computer terminal or independent, grounded USB port.

II: A computer terminal which is grounded, and the proposed USB plug is connected to the terminal, which may in turn be connected to a device intended to make contact with a biological or non-biological body. Such a device may take the form of a grounding pad, grounding acupressure probe, grounding massager or other. When a body touches the grounding device connected using conductive media to the USB, the indicator light illuminates.
